(19) United States
(12) Patent Application Publication
(10) Pub. No.: US 2025/0259827 A1
(43) Pub. Date: Aug. 14, 2025

(54) PLASMA PROCESSING APPARATUS

(71) Applicant: SAMSUNG ELECTRONICS CO., LTD., Suwon-si (KR)

(72) Inventors: Minyoung Hur, Suwon-si (KR); Donghyeon Na, Suwon-si (KR); Kyungsun Kim, Suwon-si (KR); Namkyun Kim, Suwon-si (KR); Sungyeol Kim, Suwon-si (KR); Hyunbae Kim, Suwon-si (KR); Hwasoo Seok, Suwon-si (KR); Kuihyun Yoon, Suwon-s (KR); Sungyong Lim, Suwon-si (KR)

(73) Assignee: SAMSUNG ELECTRONICS CO., LTD., Suwon-si (KR)

(21) Appl. No.: 18/811,382

(22) Filed: Aug. 21, 2024

(30) Foreign Application Priority Data
Feb. 13, 2024 (KR) 10-2024-0020139

(51) Int. Cl. H01J 37/32

(52) U.S. Cl. CPC H01J 37/32568; H01J 37/32715; H01J 2237/04735; H01J 2237/2007; H01J 2237/334

(57) ABSTRACT

A plasma processing apparatus includes a chamber body including a chamber, an electrostatic chuck supporting a substrate within the chamber body and including a lower electrode, a high-frequency power supply device configured to supply high-frequency power to generate plasma with gas supplied to the chamber, and a bias power supply device configured to supply pulse power for ion acceleration to the lower electrode. The bias power supply device is configured to supply a positive voltage pulse having a duty ratio of (1-D) to the lower electrode when a target duty ratio D of an acceleration period for accelerating ions in the plasma during a process cycle exceeds a threshold.

### CROSS-REFERENCE TO RELATED APPLICATION

This application claims priority from Korean Patent Application No. 10-2024-0020139 filed on Feb. 13, 2024, in the Korean Intellectual Property Office, the disclosure of which is incorporated by reference herein in its entirety.

### BACKGROUND

The present disclosure relates to a plasma processing apparatus.

Plasma processing apparatuses are used to manufacture semiconductor devices. A plasma processing apparatus generally includes a chamber body, a stage, and a high-frequency power supply. The chamber body includes an internal space thereof as a chamber. The chamber body is grounded. The stage is provided in the chamber and is configured to support the substrate disposed thereon. The stage includes a lower electrode. The high-frequency power supply supplies high frequencies to excite gas in the chamber. In a plasma processing apparatus, ions are accelerated by a potential difference between the potential of a lower electrode and the potential of plasma, and the accelerated ions are irradiated on the substrate.

As a type of plasma processing apparatus, a plasma processing apparatus configured to supply high frequency waves for bias to a lower electrode may be used. High frequency for bias may be supplied to the lower electrode to increase the energy of ions irradiated on the substrate and increase an etching rate of the substrate.

### SUMMARY

One or more example embodiments provide a plasma processing apparatus in which Unit Per Equipment Hour (UPEH) may be increased while suppressing an increase in power consumption for supplying high frequencies for bias.

One or more example embodiments provide a plasma processing apparatus in which a search range of a duty ratio of an etching period may be extended to optimize an etching period, a passivation period, and an exhaust period in a plasma process cycle.

According to an aspect of one or more example embodiments, a plasma processing apparatus includes: a chamber body including a chamber; an electrostatic chuck supporting a substrate within the chamber body and including a lower electrode; a high-frequency power supply device configured to supply high-frequency power to generate plasma with gas supplied to the chamber; and a bias power supply device configured to supply pulse power configured for ion acceleration to the lower electrode, wherein the bias power supply device is configured to apply a positive voltage pulse having a duty ratio of (1-D) to the lower electrode, where D is a real number between 0 and 1, when a target duty ratio D of an acceleration period for accelerating ions in the plasma during a process cycle is greater than a threshold.

According to a further aspect of one or more example embodiments, a plasma processing apparatus includes: a chamber body including a chamber; an electrostatic chuck supporting a substrate within the chamber body and including a lower electrode; a high-frequency power supply device configured to supply high-frequency power to generate plasma with gas supplied to the chamber; and a bias power supply device configured to supply non-sinusoidal power to the lower electrode for ion acceleration, wherein the bias power supply device is configured to control a direct current level of the non-sinusoidal power using a ratio of a first acceleration period during a process cycle, in which ions in the plasma are accelerated to have a first energy, a ratio of a second acceleration period during which ions in the plasma are accelerated to have a second energy, and a ratio of a rest period excluding the first acceleration period and the second acceleration period.

According to a still further aspect of one or more example embodiments, a plasma processing apparatus includes: a chamber body including a chamber; an electrostatic chuck supporting a substrate within the chamber body and including a lower electrode; a high-frequency power supply device configured to supply high-frequency power to generate plasma with gas supplied to the chamber; and a bias power supply device configured to supply non-sinusoidal power to the lower electrode for ion acceleration, wherein the bias power supply device is configured to control a direct current level of the non-sinusoidal power, such that a zero voltage is applied to the lower electrode during a longest period among one or more acceleration periods for accelerating ions in the plasma and a rest period excluding the one or more acceleration periods during one process cycle.

### BRIEF DESCRIPTION OF DRAWINGS

The above and other aspects, features, and advantages will be more apparent from the following detailed description of one or more example embodiments, taken in conjunction with the accompanying drawings, in which:

FIG. 1 is a diagram illustrating a plasma processing apparatus according to one or more example embodiments;

FIG. 2 is a diagram illustrating substrate voltage, bias voltage, bias current, and power consumption over time in an etching process cycle, according to one or more example embodiments;

FIG. 3 is a diagram illustrating DC self-bias characteristics of plasma, according to one or more example embodiments;

FIGS. 4A and 4B are diagrams for comparing and illustrating substrate voltage, bias voltage, bias current, and power consumption over time in one or more example embodiments and a comparative example;

FIGS. 5A, 5B and 5C are diagrams illustrating simulation results of substrate voltage and Ion Energy Distribution Function (IEDF) according to bias voltage in one cycle of an etching process, according to one or more example embodiments;

FIGS. 6A, 6B and 6C are diagrams illustrating simulation results of substrate voltage and IEDF according to bias voltage in one cycle of an etching process;

FIG. 7 is a diagram illustrating a bias power circuit according to one or more example embodiments;

FIG. 8 is a diagram illustrating bias voltage according to a switching state of a bias power circuit, according to one or more example embodiments;

FIGS. 9A and 9B are diagrams illustrating switching state control according to bias voltage, according to one or more example embodiments;

FIG. 10 is a diagram illustrating an etching process cycle according to one or more example embodiments;

FIGS. 11A, 11B and 11C are diagrams illustrating simulation results of substrate voltage and IEDF according to bias voltage in one cycle of an etching process, according to one or more example embodiments; and

FIGS. 12A, 12B and 12C illustrate the bias voltage according to the duty ratio of the first acceleration period, the second acceleration period, and the rest period during the etching process cycle, according to one or more example embodiments; and

FIGS. 13A, 13B and 13C illustrate the bias voltage according to the duty ratio of the first acceleration period, the second acceleration period, and the rest period during the etching process cycle.

### DETAILED DESCRIPTION

According to one or more example embodiments, one or more example embodiments will be described with reference to the accompanying drawings.

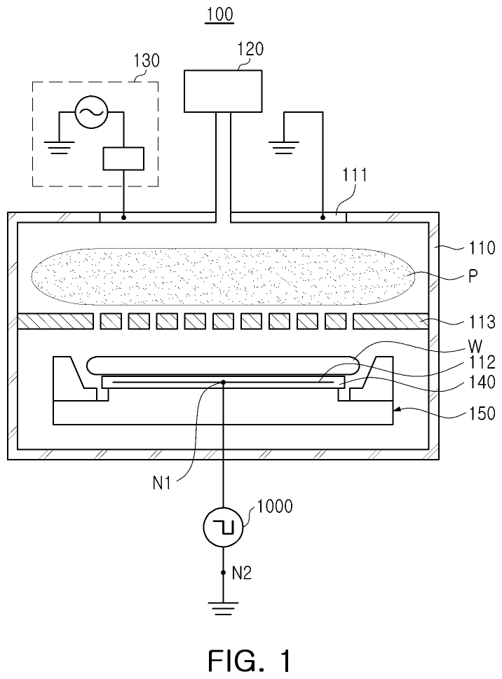

FIG. 1 is a diagram illustrating a plasma processing apparatus according to one or more example embodiments.

Referring to FIG. 1, a plasma processing apparatus 100 according to one or more example embodiments may include a chamber body 110, a process gas supply unit 120, a high-frequency power supply device 130, an electrostatic chuck 140, a lower structure 150, and a bias power supply device 1000. Additionally, the plasma processing apparatus 100 may further include a cooling device, an exhaust unit, a controller, and the like.

The chamber body 110 may serve as a housing forming a chamber defined by an outer wall. The chamber may be used to perform an etching process for processing a substrate W to be processed using plasma P generated by exciting the process gas supplied by the process gas supply unit 120. The outer wall may be formed of a material with excellent wear resistance and corrosion resistance. The chamber may maintain the internal space thereof in a sealed state with a predetermined pressure and temperature during a plasma process, for example, an etching process. A pump may be disposed on the outer wall of the chamber body 110 to exhaust gas in the internal space.

The chamber body 110 may include an upper electrode 111 and an induction electrode 113. For example, the chamber may be divided by the induction electrode 113, and the process gas supply unit 120 may supply process gas for forming plasma P in the chamber space between the upper electrode 111 and the induction electrode 113.

The process gas supply unit 120 may supply process gas for performing a plasma process to the chamber. For example, the process gas may include O₂, Cl₂, SF₆, and the like.

The structure of the upper electrode 111 may not be limited to the one or more example embodiments illustrated in FIG. 1. For example, the process gas supply unit 120 may have a structure connected to the upper electrode 111. According to one or more example embodiments, the upper electrode 111 may be a showerhead-shaped electrode, and the process gas supplied from the process gas supply unit 120 may be injected into the chamber through the injection hole of the upper electrode 111. Depending on one or more example embodiments, the upper electrode 111 may be disposed on an upper portion or a side portion of the chamber body 110.

The supplied process gas may be converted into a plasma state by power supplied from the high-frequency power supply device 130. The high-frequency power supply device 130 may be connected to the upper electrode 111 and may supply high-frequency power for plasma generation to the upper electrode 111.

In the plasma processing apparatus 100 according to one or more example embodiments, the supplied high-frequency power may be a Radio frequency (RF) voltage, and the RF voltage may form a high-frequency electric field between the upper electrode 111 and the induction electrode 113. A high-frequency electric field may excite the process gas supplied inside the chamber body 110 into a plasma P state.

The electrostatic chuck 140 may be disposed inside the chamber body 110 where a plasma process is performed, and the substrate W may be fixed to the upper surface of the electrostatic chuck 140 using static electricity. The electrostatic chuck 140 may include a lower electrode 112.

A substrate W may be disposed between the induction electrode 113 and the lower electrode 112, and a plasma process may be performed by ions included in the plasma P being accelerated and the accelerated ions being irradiated on the substrate W. For example, the lower electrode 112 may be included in the electrostatic chuck 140. The lower electrode 112 may have a circular planar shape to support the circular substrate W, but one or more example embodiments are not limited thereto.

The lower structure 150 may support the electrostatic chuck 140. In one or more example embodiments, if the temperature of the substrate W increases due to heat generated during the plasma process, the lower structure 150 may further include an edge ring used to control the temperature in the edge area of the substrate W. For example, the edge ring may be arranged to surround the side of the substrate W and may be spaced apart from the side of the substrate W.

In a plasma process, the upper electrode 111 and the lower electrode 112 may generate reflected power. As the reflected power increases, the overall output for plasma formation may decrease. Therefore, an impedance matcher may minimize reflected power by matching the impedance of the circuit and the power source. For example, high-frequency power output from the high-frequency power supply device 130 may be supplied to the upper electrode 111 through an impedance matcher. FIG. 1 illustrates only the impedance matcher included in the high frequency power supply device 130, but one or more example embodiments are not limited thereto.

The lower electrode 112 may receive non-sinusoidal power from the bias power supply device 1000. For example, periodic negative voltage pulses may be applied to the substrate W by non-sinusoidal power supplied to the lower electrode 112. When the plasma process is an etching process, positive ions contained in the plasma P may be accelerated during the acceleration period when the negative voltage pulse is applied during the process cycle, and the substrate W may be etched by accelerated positive ions colliding with the substrate W. During the process cycle, a passivation operation, an exhaust operation, etc. may be performed during a rest period excluding the acceleration period.

Non-sinusoidal power may have the advantage of being able to fine-tune the acceleration period of the plasma treatment process compared to sinusoidal Radio Frequency (RF) power. Although it is difficult to adjust the ratio of the acceleration period during the process cycle with sinusoidal power, the bias power supply device 1000 may adjust the ratio of the acceleration period by adjusting the duty ratio of the negative voltage pulse applied to the substrate W.

The higher the duty ratio, the longer the substrate W may be etched in one process cycle, and because the time required to etch the substrate W by the target etching amount may be shortened, Unit Per Equipment Hour (UPEH) may increase. As the maximum duty ratio increases, the search range for determining the optimal duty ratio during the etching process may become wider.

However, in order for the bias power supply device 1000 to apply a negative voltage pulse to the substrate W, if a negative voltage is uniformly supplied to the lower electrode 112 during the acceleration period and a zero voltage is supplied to the lower electrode 112 during the rest period, as the duty ratio is increased, the time for which the negative voltage is applied becomes longer, and thus the power consumption of the bias power supply device 1000 may increase.

According to one or more example embodiments, the bias power supply device 1000 uses the direct current (DC) self-bias characteristics of plasma to supply a zero voltage to the lower electrode 112 during the acceleration period and a positive voltage to the lower electrode 112 during the rest period, and may be controlled so that a negative voltage is applied to the substrate W during the acceleration period and a plasma voltage having a weak positive voltage is applied to the substrate W during the rest period.

In the case in which the target duty ratio D of the negative voltage pulse applied to the substrate W during the process cycle exceeds 0.5 (50%), the bias power supply device 1000 may apply a positive voltage pulse having a duty ratio of (1-D) to the lower electrode 112, thereby reducing the time during which a voltage other than zero voltage is applied during the process cycle and reducing power consumption of the bias power supply device 1000 (where D is a real number between 0 and 1).

According to one or more example embodiments, the bias power supply device 1000 may increase the maximum duty ratio while suppressing an increase in power consumption. Therefore, the UPEH of the etching process may be increased, and the search range for determining the optimal duty ratio may be expanded.

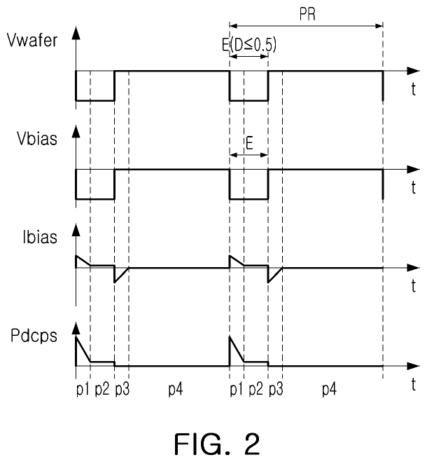

According to one or more example embodiments, with reference to FIG. 2, the etching process cycle of a plasma processing apparatus 100 and the power consumption of the bias power supply device 1000 according to the etching period during the etching process cycle will be described in detail.

FIG. 2 is a diagram illustrating substrate voltage, bias voltage, bias current, and power consumption over time in the plasma process cycle, according to one or more example embodiments.

Referring to FIG. 2, the substrate voltage Vwafer formed on the lower surface of the substrate over time during the plasma process is illustrated. A plurality of operations may be performed in chronological order during the process cycle PR. For example, when the plasma process is an etching process, an etching operation, a passivation operation, an exhaust operation, etc. may be performed during the process cycle PR.

During the acceleration period E, during which the etching operation is performed, a strong negative voltage of, for example, several thousand volts may need to be formed on the bottom of the substrate. When a negative voltage is formed on the bottom of the substrate, positive ions contained in the plasma formed on the upper part of the substrate are accelerated toward the substrate, and the positive ions collide with the substrate, thereby etching the substrate. During a rest period in which an etching operation is not performed, a plasma voltage having a weak positive voltage close to zero voltage may be formed on the lower surface of the substrate. During the rest period, the etching operation may be stopped, and a passivation operation, an exhaust operation, etc. may be performed.

Referring to FIG. 2, a bias voltage Vbias that may be applied to the lower electrode 112 to control the substrate voltage Vwafer during the etching process is illustrated. The bias power supply device 1000 described with reference to FIG. 1 has a negative voltage during the acceleration period E of the etching process cycle PR, and the bias power supply device 1000 may control the substrate voltage Vwafer by applying repeated negative voltage pulses to the lower electrode 112 to have a zero voltage during the rest period.

Referring to FIG. 2, a bias current Ibias generated in the load, while the bias power supply device 1000 applies a bias voltage Vbias to the lower electrode 112, is illustrated. The process cycle PR may include: a voltage charging period p1 for charging the bias voltage Vbias from zero voltage to negative voltage, a voltage maintenance period p2 maintaining the bias voltage Vbias at a negative voltage, a voltage discharge period p3 changing the bias voltage Vbias from negative voltage to zero voltage, and a zero voltage period p4 during which the bias voltage Vbias is maintained at zero voltage. Peak current may occur in the load during the voltage charging period p1 and voltage discharge period p3, and continuous current may occur in the load during the voltage maintenance period p2.

Referring to FIG. 2, DC power Pdcps consumed by the bias power supply device 1000 to apply a bias voltage Vbias is illustrated. DC power Pdcps may be determined as a product of the bias voltage Vbias applied to the load and the bias current Ibias flowing through the load. Peak power may occur during the voltage charging period p1, and power may be continuously consumed during the voltage maintenance period p2. Additionally, power may not be consumed during the voltage discharge period p3 and the zero voltage period p4.

Referring to FIG. 2, if the bias voltage Vbias has a negative voltage during the acceleration period E and a zero voltage during the rest period, the period in which DC power Pdcps occurs may coincide with the acceleration period E. As the target etching period of the plasma etching device 100 becomes longer, the period during which DC power Pdcps is generated may become longer, and the amount of power consumed during the process cycle PR may increase.

According to one or more example embodiments, when the target duty ratio D of the substrate voltage Vwafer is 0.5 or less, the bias power supply device 1000 may apply a bias voltage Vbias having a negative voltage during the acceleration period E and a zero voltage during the rest period to the lower electrode 112. When the target duty ratio D exceeds 0.5, the bias power supply device 1000 may apply a bias voltage Vbias having a zero voltage during the acceleration period E and a positive voltage during the rest period to the lower electrode 112.

Due to the DC self-bias characteristics of plasma, even when the bias power supply device 1000 applies a bias voltage Vbias having a zero voltage during the acceleration period E and a positive voltage during the rest period to the lower electrode, the substrate voltage Vwafer may be controlled to have a negative voltage during the acceleration period E and to have a plasma voltage during the rest period.

According to one or more example embodiments, the bias power supply device 1000 may reduce the power consumption time to equal to or less than 0.5 times the etching process cycle PR even when the target duty ratio D exceeds 0.5. For example, the bias power supply device 1000 may increase the maximum duty ratio of the substrate voltage Vwafer while suppressing power consumption, and may increase the range of possible duty ratios.

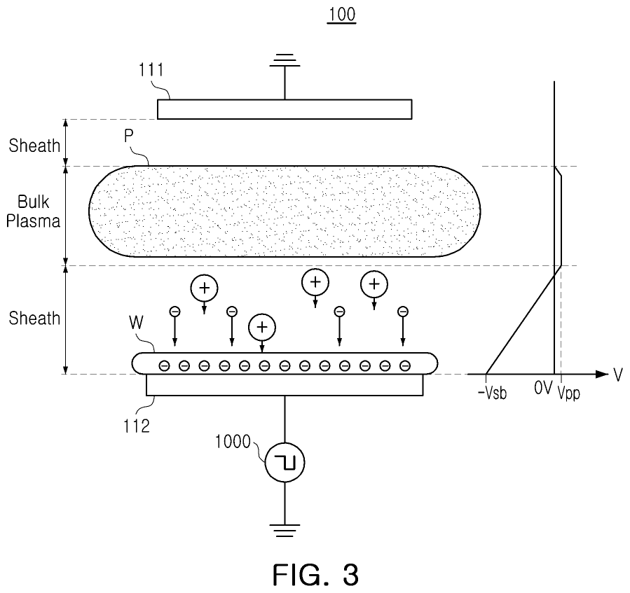

Below, the DC self-bias characteristics of the plasma are described in detail with reference to one or more example embodiments consistent with FIG. 3.

FIG. 3 is a diagram to explain the DC self-bias characteristics of plasma, according to one or more example embodiments.

FIG. 3 illustrates the upper electrode 111, the lower electrode 112, and the bias power supply device 1000 of the plasma etching device 100 as described with reference to one or more example embodiments consistent with FIG. 1.

A bulk plasma region and a sheath region may be formed between the upper electrode 111 and the lower electrode 112. For example, a sheath region may be formed around the bulk plasma region between the upper electrode 111 and the lower electrode 112. The bulk plasma region may have a higher plasma density than the sheath region. In FIG. 3, plasma P formed in the bulk plasma region is illustrated. In FIG. 3, positive ions (+) and electrons (−) that may be included in the plasma of the sheath region between the bulk plasma region and the lower electrode 112 are illustrated.

When a periodic signal is applied to the lower electrode 112 while plasma is formed, the direct current level on the bottom of the substrate may move in the direction in which the electron flux and ion flux during one cycle of the signal coincide.

In general, the mass of a positive ion (+) may be 10,000 or more times greater than the mass of an electron (−). Therefore, the mobility of electrons (−) may be higher than that of positive ions (+). For example, when a positive voltage is applied to the lower electrode 112, the movement speed of electrons (−) may be faster than the movement speed of positive ions (+) when a negative voltage is applied. Accordingly, the direct current level Vsb on the surface of the lower electrode 112 may move in the negative direction so that the electron flux and ion flux coincide.

FIG. 3 illustrates the direct current level of plasma depending on the position inside the chamber space, according to one or more example embodiments. The bulk plasma region may have a plasma voltage Vpp. As the plasma voltage Vpp approaches the lower electrode 112, the direct current level of the plasma may be lowered in the sheath region between the bulk plasma region and the lower electrode 112.

Meanwhile, the direct current level Vsb formed on the lower surface of the substrate W is determined by the amount of movement of positive ions (+) and electrons (−) in one cycle, and the direct current level Vsb is affected by the amplitude of the bias voltage Vbias applied to the lower electrode 112, and may be determined almost independently of the direct current level. For example, changing only the DC level of the bias voltage Vbias may have little effect on the DC level Vsb formed on the lower surface of the substrate W.

According to one or more example embodiments, the bias power supply device 1000 applies a bias voltage Vbias having a zero voltage during the acceleration period E and a positive voltage during the rest period to the lower electrode. The substrate voltage Vwafer may be controlled to have a negative voltage during the acceleration period E and a plasma voltage Vpp during the rest period.

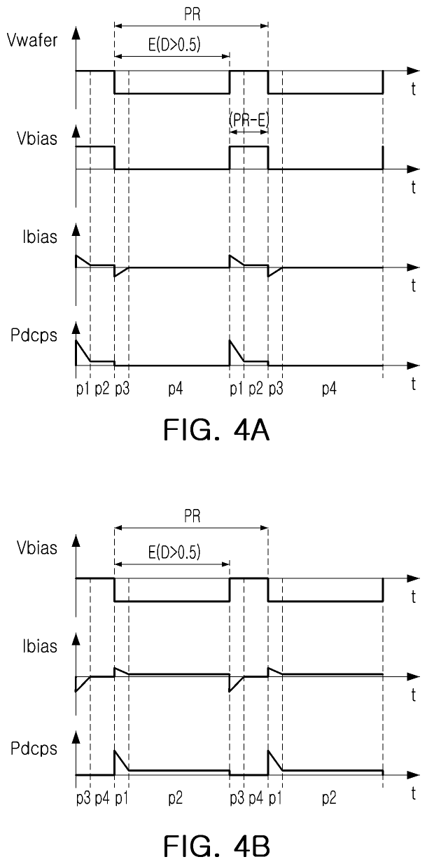

FIGS. 4A and 4B are diagrams for comparing and illustrating the substrate voltage, bias voltage, bias current, and power consumption over time in one or more example embodiments and a comparative example.

Referring to FIG. 4A, the substrate voltage Vwafer to be formed on the lower surface of the substrate over time during the etching process is illustrated. Similar to that described with reference to FIG. 2, the process cycle PR may include an acceleration period E. During the acceleration period E, during which the etching operation is performed, a strong negative voltage of, for example, several thousand volts may need to be applied to the bottom of the substrate. In the example of FIG. 4A, the target duty ratio D of the acceleration period E during the etching process cycle PR may exceed 0.5.

Referring to FIG. 4A, a bias voltage Vbias that may be applied to the lower electrode 112 to control the substrate voltage Vwafer in the etching process is illustrated.

According to one or more example embodiments, the bias power supply device 1000 described with reference to FIG. 1 may control the substrate voltage Vwafer by repeatedly applying a bias voltage Vbias to the lower electrode 112 to have a zero voltage during the acceleration period E of the etching process cycle PR and a positive voltage during the rest period (PR-E). For example, the bias power supply device 1000 may apply a bias voltage Vbias whose duty ratio of the positive voltage is (1-D) when the target duty ratio D of the substrate voltage Vwafer exceeds 0.5.

As described with reference to FIG. 3, due to the DC self-bias characteristics of plasma, the substrate voltage Vwafer is almost unaffected by the DC level of the bias voltage Vbias. When the bias voltage Vbias has a positive voltage level, it may have a plasma voltage Vpp, and when it has a zero voltage level, it may have a negative voltage level. Therefore, by applying a bias voltage Vbias whose duty ratio of the positive voltage is less than 0.5, a target duty ratio D exceeding 0.5 may be provided to the substrate voltage Vwafer.

Referring to FIG. 4A, a bias current Ibias generated in the load while the bias power supply device 1000 applies a bias voltage Vbias to the lower electrode 112 is illustrated, according to one or more example embodiments. The etching process cycle PR may include a voltage charging period p1 for charging the bias voltage Vbias from zero voltage to negative voltage, a voltage maintenance period p2 maintaining the bias voltage Vbias at a negative voltage, a voltage discharge period p3 changing the bias voltage Vbias from negative voltage to zero voltage, and a zero voltage period p4 during which the bias voltage Vbias is maintained at zero voltage.

Referring to FIG. 4A, DC power Pdcps consumed by the bias power supply device 1000, to apply a bias voltage Vbias, is illustrated. As described with reference to FIG. 2, peak power may occur during the voltage charging period p1, and power may be continuously consumed during the voltage maintenance period p2. Additionally, power may not be consumed during the voltage discharge period p3 and the zero voltage period p4. For example, referring to FIG. 4A, power may be consumed at a time corresponding to a duty ratio of (1-D), which is shorter than the target duty ratio D.

Referring to FIG. 4B, a bias voltage Vbias that may be applied to the lower electrode 112 to control the substrate voltage Vwafer according to a comparative example different from one or more example embodiments described above, is illustrated. According to a comparative example, as illustrated in FIG. 4A, a bias voltage Vbias having a duty ratio of a negative voltage D may be applied to control the substrate voltage Vwafer, whose duty ratio D exceeds 0.5.

Referring to FIG. 4B, as described according to one or more example embodiments with reference to FIG. 2, peak power may occur during the voltage charging period p1, and power may be continuously consumed during the voltage maintenance period p2. Additionally, power may not be consumed during the voltage discharge period p3 and the zero voltage period p4. For example, when applying a bias voltage Vbias whose duty ratio of negative voltage is D, power may be consumed in a time corresponding to the duty ratio D. For example, the bias power supply device according to the comparative example of FIG. 4B may consume power for a longer period of time than the bias power supply device 1000 according to one or more example embodiments described with reference to FIG. 4A.

According to one or more example embodiments, when the target duty ratio D of the substrate voltage Vwafer exceeds 0.5, the bias power supply device 1000 may reduce power consumption by applying a voltage with a positive voltage duty ratio of (1-D).

According to one or more example embodiments, in a case of applying a negative voltage pulse having a duty ratio equal to the target duty ratio D of the substrate voltage Vwafer to the lower electrode 112, and in a case of applying a positive voltage pulse having a duty ratio of (1-D), simulation results illustrating that the substrate voltage Vwafer has substantially the same waveform are described.

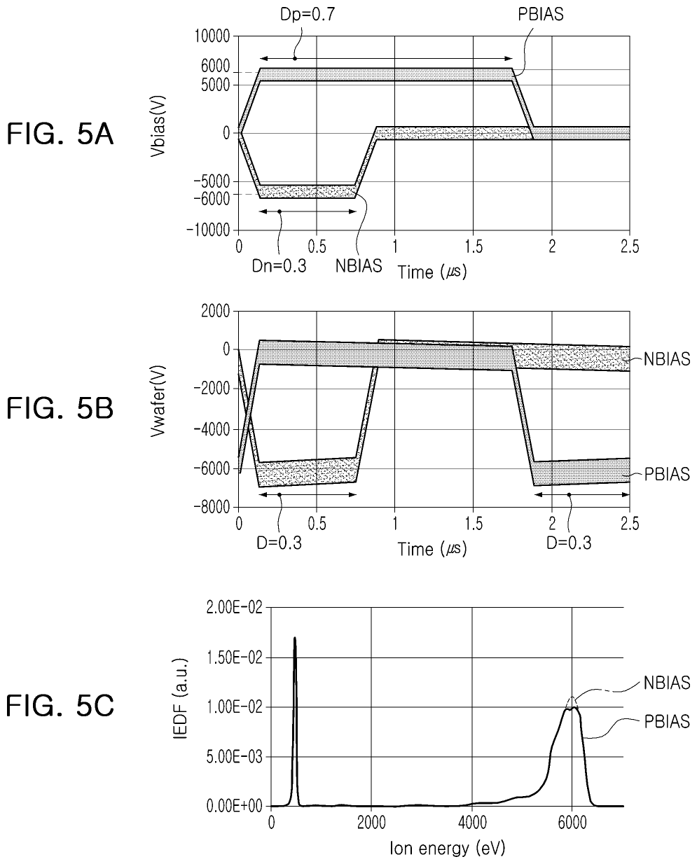

FIGS. 5A, 5B and 5C are diagrams illustrating simulation results of substrate voltage and Ion Energy Distribution Function (IEDF) according to bias voltage during one cycle of the etching process.

Referring to FIG. 5A, during the etching process cycle, an example of the bias voltage over time is illustrated when a negative bias voltage NBIAS in which a negative voltage pulse has a duty ratio of 0.3 (Dn=0.3) is applied to the lower electrode 112 and when a positive bias voltage PBIAS in which the positive voltage pulse has a duty ratio of 0.7 (Dp=0.7) is applied thereto.

The magnitude of the negative voltage pulse of the negative bias voltage NBIAS and the positive voltage pulse of the positive bias voltage PBIAS may be substantially the same. For example, a negative voltage pulse may have a potential of −6000V, and a positive voltage pulse may have a potential of +6000V. The duty ratio (Dn) of the negative voltage pulse and the duty ratio (Dp) of the positive voltage pulse may have a relationship of (Dp=1−Dn).

In the example of FIG. 5A, because the duty ratio (Dn) of the negative voltage pulse is shorter than the duty ratio (Dp) of the positive voltage pulse, during the etching process cycle, the power consumption of the negative bias voltage NBIAS may be lower than the power consumption of the positive bias voltage PBIAS.

FIG. 5B illustrates the substrate voltage Vwafer over time when the negative bias voltage NBIAS is applied to the lower electrode 112 during the etching process cycle and when the positive bias voltage PBIAS is applied.

When a negative bias voltage NBIAS is applied to the lower electrode 112, the substrate voltage Vwafer may have a negative voltage pulse having the same duty ratio (D=0.3) and the same potential as the negative voltage pulse of the negative bias voltage NBIAS. When a positive bias voltage PBIAS is applied to the lower electrode 112, due to the DC self-bias characteristics of the substrate, the DC level of the positive bias voltage PBIAS may be lowered. As a result, the substrate voltage Vwafer may have the same magnitude as the positive voltage pulse of the positive bias voltage and may have a negative voltage pulse having a duty ratio of (1−Dp).

As a result, a negative bias voltage NBIAS with negative voltage pulses having a duty ratio of Dn and a positive bias voltage PBIAS with positive voltage pulses of the same magnitude having a duty ratio of (Dp=1−Dn) are applied. According to one or more example embodiments, the duty ratio D and magnitude of the negative voltage pulses of the substrate voltage Vwafer may be substantially the same.

Referring to FIG. 5C, the IEDF is illustrated when a negative bias voltage NBIAS is applied to the lower electrode 112 and when a positive bias voltage PBIAS is applied during the etching process cycle. When the negative bias voltage NBIAS is applied, and when the positive bias voltage PBIAS is applied, the ion energy distribution may be almost the same. For example, in both cases, the distribution of ion energy may be formed centered around 6000 eV.

According to one or more example embodiments, when the target duty ratio D of the substrate voltage Vwafer is 0.5 or less, power consumption may be reduced by applying a voltage in which the duty ratio of the negative voltage pulse is the same voltage as the target duty ratio D to the lower electrode 112 as a bias voltage Vbias.

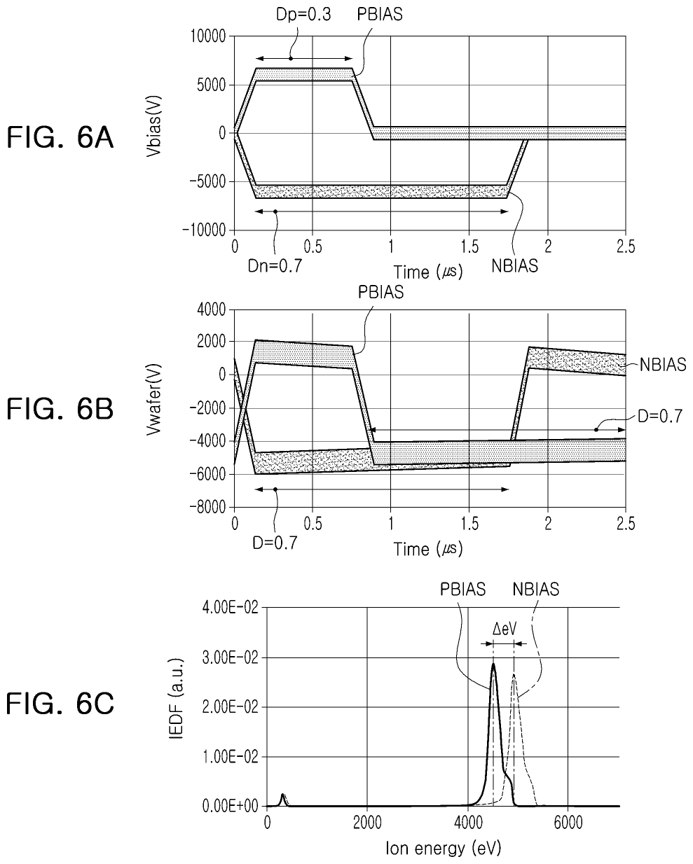

FIGS. 6A, 6B and 6C are diagrams illustrating simulation results of substrate voltage and IEDF according to bias voltage during one cycle of the etching process, according to one or more example embodiments.

Referring to FIG. 6A, during the etching process cycle, in the case where a negative bias voltage NBIAS in which the negative voltage pulse has a duty ratio of 0.7 (Dn=0.7) is applied to the lower electrode 112, and in the case where a positive bias voltage PBIAS in which the positive voltage pulse has a duty ratio of 0.3 (Dp=0.3) is applied, an example of the bias voltage over time is illustrated.

The magnitudes of the negative voltage pulse of the negative bias voltage NBIAS and the positive voltage pulse of the positive bias voltage PBIAS may be substantially the same. For example, a negative voltage pulse may have a potential of −6000V, and a positive voltage pulse may have a potential of +6000V. The duty ratio (Dn) of the negative voltage pulse and the duty ratio (Dp) of the positive voltage pulse may have a relationship of (Dp=1−Dn).

In the one or more example embodiments of FIG. 6A, because the duty ratio (Dp) of the positive voltage pulse is shorter than the duty ratio (Dn) of the negative voltage pulse, during the etching process cycle, the power consumption of the positive bias voltage PBIAS may be lower than the power consumption of the negative bias voltage NBIAS.

FIG. 6B illustrates the substrate voltage Vwafer over time when the negative bias voltage NBIAS is applied to the lower electrode 112 during the etching process cycle and when the positive bias voltage PBIAS is applied, according to one or more example embodiments.

When a negative bias voltage NBIAS is applied to the lower electrode 112, the substrate voltage Vwafer may have a negative voltage pulse having the same duty ratio (D=0.7) and the same potential as the negative voltage pulse of the negative bias voltage NBIAS. When the positive bias voltage PBIAS is applied to the lower electrode 112, the direct current (DC) level of the positive bias voltage PBIAS may be lowered due to the DC self-bias characteristics of the substrate. As a result, the substrate voltage Vwafer may have a negative voltage pulse having a duty ratio of (1−Dp) and the same magnitude as the positive voltage pulse of the positive bias voltage.

As a result, even when the target duty ratio D is greater than 0.5, in the case of applying a negative bias voltage NBIAS with a negative voltage pulse having a duty ratio of Dn and a positive bias voltage PBIAS having a duty ratio of (Dp=1−Dn) and a positive voltage pulse of the same magnitude, the duty ratio D of the negative voltage pulse of the substrate voltage Vwafer may be substantially the same.

Referring to FIG. 6C, the IEDF is illustrated when a negative bias voltage NBIAS is applied to the lower electrode 112 during the etching process cycle and when a positive bias voltage PBIAS is applied.

In the example of FIG. 6C, the ion energy when applying the positive bias voltage PBIAS may be about 7% lower than the ion energy when applying the negative bias voltage NBIAS. This difference may be offset by increasing the size of the positive ion pulse of the positive bias voltage PBIAS by about 7%.

According to one or more example embodiments, when the target duty ratio D of the substrate voltage Vwafer is greater than 0.5, power consumption may be reduced by applying a voltage having a duty ratio (1-D) of the positive voltage pulse to the lower electrode 112 as a bias voltage Vbias.

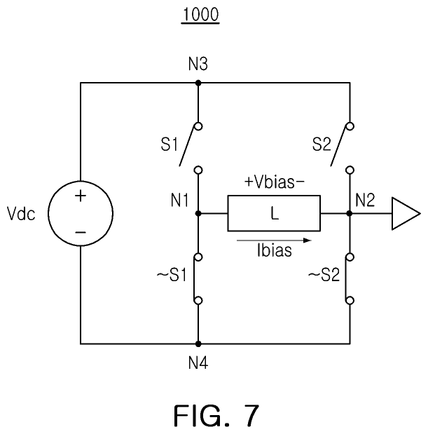

Below, an example of the structure and operation method of the bias power supply device 1000 according to one or more example embodiments is described in detail with reference to FIGS. 7, 8 and 9.

FIG. 7 is a diagram illustrating a bias power circuit according to one or more example embodiments.

Referring to FIG. 7, the bias power circuit 1000 may include a direct current power source Vdc, a first switch pair S1, ˜S1, a second switch pair S2, ˜S2, and a load L.

The load L may be connected to the first node N1 and the second node N2. The first node N1 and the second node N2 may correspond to the first node N1 and the second node N2 illustrated in FIG. 1. For example, the first node N1 may be connected to the lower electrode 112 of FIG. 1, and the second node N2 may be connected to ground. A bias voltage Vbias may be applied to the load L between the first node N1 and the second node N2, and a bias current Ibias may flow.

The direct current power source Vdc may apply a bias voltage Vbias between the first node N1 and the second node N2. The direct current power source Vdc may be connected between the third node N3 and the fourth node N4.

The first switch pair S1, ˜S1 may include a first switch S1 and a first complementary switch ˜S1, operating complementary. The fact that the first switch S1 and the first complementary switch ˜S1 operate complementary, may refer to the fact that the first complementary switch ˜S1 is in an OFF state when the first switch S1 is in the ON state, and the first complementary switch ˜S1 is in the ON state when the first switch S1 is in the OFF state.

The first switch S1 may be connected between the third node N3 and the first node N1, and the first complementary switch ˜S1 may be connected between the first node N1 and the fourth node N4. The first switch S1 and the first complementary switch ˜S1 operate complementary to selectively connect the first node N1 to the third node N3 or the fourth node N4.

The second switch pair S2, ˜S2 may include a second switch S2 and a second complementary switch ˜S2 that operate complementary. The second switch S2 may be connected between the third node N3 and the second node N2, and the second complementary switch ˜S2 may be connected between the fourth node N4 and the second node N2. The second switch S2 and the second complementary switch ˜S2 operate complementary to selectively connect the second node N2 to the third node N3 and the fourth node N4.

The direct current power source Vdc may apply a positive voltage, a zero voltage, or a negative voltage between the first node N1 and the second node N2 depending on whether the first switch pair S1, ˜S1 and the second switch pair S2, ˜S2 are ON/OFF.

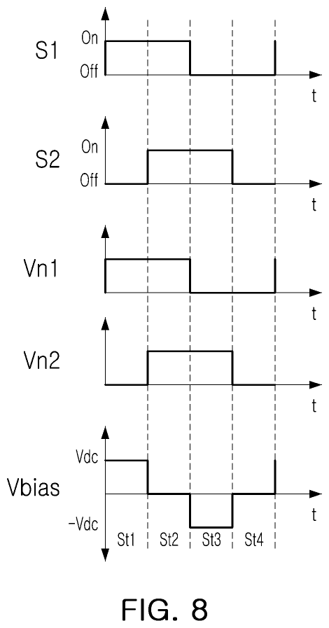

FIG. 8 is a diagram illustrating the bias voltage according to the switching state of the bias power circuit, according to one or more example embodiments.

FIG. 8 is a diagram illustrating the first node voltage Vn1, the second node voltage (Vn2), and the bias voltage Vbias according to the switching states of the first switch S1 and the second switch S2.

Referring to FIG. 8, the first switch S1 and the second switch S2 may have four switching states St1, St2, St3, and St4.

Referring to FIGS. 7 and 8, in the first switching state St1, in which the first switch S1 is ON and the second switch S2 is OFF, the positive pole of the direct current power source Vdc may be connected to the first node N1, and the negative pole of the direct current power source Vdc may be connected to the second switch. Therefore, in the first switching state St1, the bias voltage Vbias may have a positive voltage of the same magnitude as the direct current power source Vdc.

In the second switching state St2, in which the first switch S1 is turned ON and the second switch S2 is turned on, the positive pole of the direct current power source Vdc may be connected to both the first node N1 and the second node N2. Accordingly, the bias voltage Vbias in the second switching state St2 may have a zero voltage.

In the third switching state St3, in which the first switch S1 is OFF and the second switch S2 is ON, the negative pole of the direct current power source Vdc may be connected to the first node N1, and the positive pole of the direct current power source Vdc may be connected to the second switch. Therefore, in the third switching state St3, the bias voltage Vbias may have a negative voltage of the same magnitude as the direct current power source Vdc.

In the fourth switching state (St4), in which the first switch S1 is turned OFF and the second switch S2 is turned OFF, the negative pole of the direct current power source Vdc may be connected to both the first node N1 and the second node N2. Accordingly, the bias voltage Vbias in the second switching state St2 may have a zero voltage.

The bias power supply device 1000 may further include a control unit for controlling the first switch pair S1, ˜S1 and the second switch pair S2, ˜S2. According to one or more example embodiments, the bias power supply device 1000 may control the first switch pair S1, ˜S1 and the second switch pair S2, ˜S2 to generate positive or negative voltage pulse as a bias voltage Vbias.

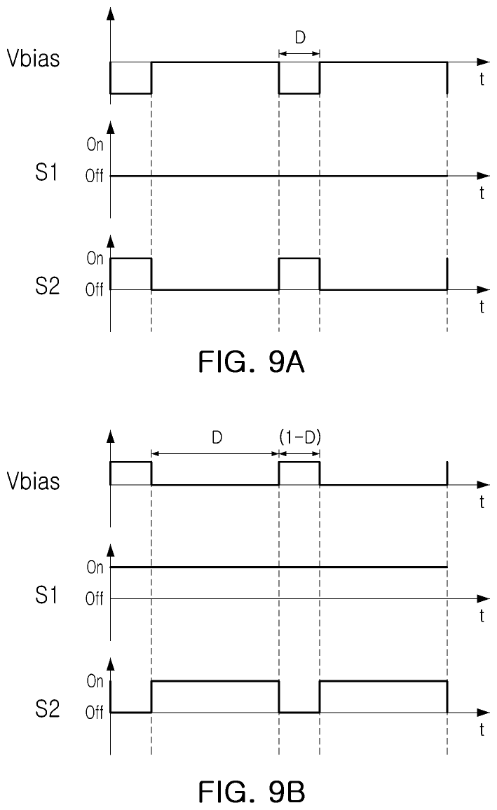

FIGS. 9A and 9B are diagrams illustrating switching state control according to bias voltage, according to one or more example embodiments.

FIG. 9A illustrates the bias voltage Vbias over time and the states of the first switch S1 and the second switch S2 when the target duty ratio D of the substrate voltage Vwafer is 0.5 or less.

As described above, when the target duty ratio D of the substrate voltage Vwafer is 0.5 or less, a negative voltage pulse having a duty ratio D may be applied as the bias voltage Vbias. In one or more example embodiments, the bias power supply device 1000 maintains the first switch S1 in the OFF state and periodically toggles the second switch S2 such that the ON state of the second switch S2 has a duty ratio D, thereby applying a bias voltage Vbias to the lower electrode 112.

However, one or more example embodiments is not limited thereto, and the bias power supply device 1000 may maintain the second switch S2 in the ON state and may periodically toggle the first switch S1 so that the ON state of the first switch S1 has a duty ratio (1-D), thereby applying a bias voltage Vbias to the lower electrode 112.

FIG. 9B illustrates the bias voltage Vbias over time and the states of the first switch S1 and the second switch S2 when the target duty ratio D of the substrate voltage Vwafer is greater than 0.5, according to one or more example embodiments.

As described above, when the target duty ratio D of the substrate voltage Vwafer is greater than 0.5, a positive voltage pulse having a duty ratio (1-D) may be applied as the bias voltage Vbias. In one or more example embodiments, the bias power supply device 1000 maintains the first switch S2 in the ON state and periodically toggles the second switch S2 so that the ON state of the second switch S2 has a duty ratio D, thereby applying a bias voltage Vbias to the lower electrode 112.

However, one or more example embodiments is not limited thereto, and the bias power supply device 1000 may maintain the second switch S2 in the OFF state and may periodically toggle the first switch S1 so that the ON state of the first switch S1 has a duty ratio (1-D), thereby applying a bias voltage Vbias to the lower electrode 112.

Referring to FIGS. 1, 2, 3, 4A, 4B, 5A, 5B, 5C, 6A, 6B, 6C, 7, 8, 9A and 9B, one or more example embodiments are described taking as an example a case in which the substrate voltage Vwafer has two states, one negative voltage state and a positive voltage state close to zero voltage, during the etching process cycle. However, one or more example embodiments are not limited thereto. For example, during an etching process cycle, the substrate voltage Vwafer may have two or more negative voltage states.

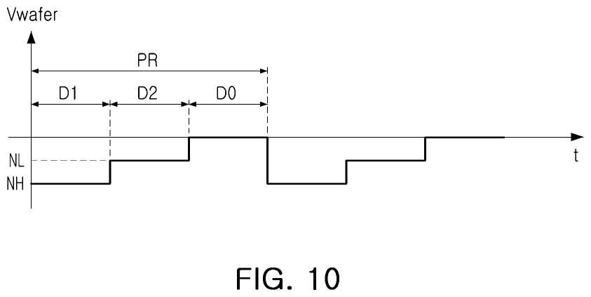

According to one or more example embodiments, a method of operating the bias power supply device 1000 when the substrate voltage Vwafer has two or more negative voltage states will be described with reference to FIGS. 10, 11A, 11B, 11C, 12A, 12B, 12C, 13A, 13B and 13C.

FIG. 10 is a diagram illustrating the etching process cycle according to one or more example embodiments.

FIG. 10 illustrates the substrate voltage Vwafer over time during the etching process cycle PR. Referring to FIG. 10, the substrate voltage Vwafer may have two or more negative voltage states. In detail, the etching process cycle PR may include a first acceleration period, during which the substrate voltage Vwafer has a relatively large first negative voltage NH, a second acceleration period during which the substrate voltage Vwafer has a relatively small second negative voltage NL, and a rest period during which the substrate voltage Vwafer has a positive voltage close to zero voltage. FIG. 10 illustrates the proportion of the first acceleration period D1, the proportion of the second acceleration period D2, and the proportion of the rest period DO during the etching process cycle PR, according to one or more example embodiments.

During the first acceleration period, positive ions in the plasma may be accelerated to have first energy by the first negative voltage NH, and during the second acceleration period, positive ions in the plasma may be accelerated to have a second energy that is lower than the first energy by the second negative voltage NL.

For example, the plasma processing apparatus 100 as described with reference to one or more example embodiments consistent with FIG. 1 may perform a coarse etching operation by colliding cations with the first energy into the substrate at the first etching time, and then may perform a fine etching operation by colliding positive ions with relatively low second energy onto the substrate during the second etching time. Also, during the rest period, passivation operations and exhaust operations may be performed.

According to one or more example embodiments, in the bias power supply device 1000, power consumption for forming the substrate voltage Vwafer may be reduced by controlling the direct current level of the bias voltage Vbias based on the ratio D1 of the first etching time and the ratio D2 of the second etching time.

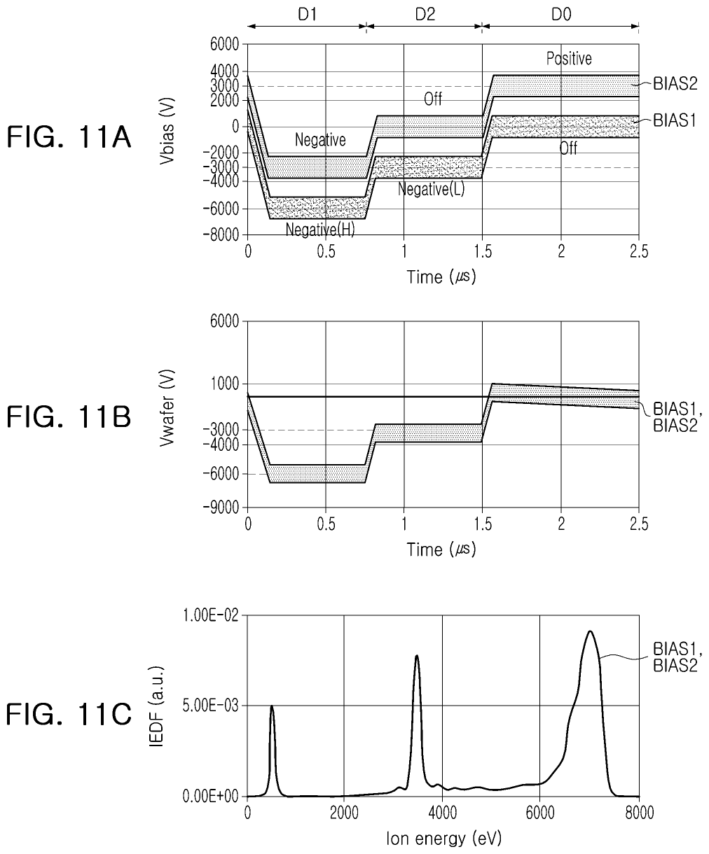

FIGS. 11A, 11B and 11C are diagrams illustrating simulation results of substrate voltage and IEDF according to bias voltage in one cycle of the etching process, according to one or more example embodiments.

FIG. 11A illustrates the bias voltage level Vbias according to time of the first bias voltage BIAS1 and the second bias voltage BIAS2 during the etching process cycle. The first bias voltage BIAS1 may have a relatively high negative voltage level of −6000V during the first etching period D1, may have a relatively low negative voltage level of −3000V during the second etching period D2, and may have a positive voltage level close to zero voltage during the rest period DO.

The second bias voltage BIAS2 may have a negative voltage level of −3000V during the first etch period D1 and a zero voltage level during the second etch period D2, and may have a positive voltage level of +3000V during the rest period DO. For example, the first bias voltage BIAS1 and the second bias voltage BIAS2 may have the same waveform and different DC levels.

FIG. 11B illustrates the substrate voltage Vwafer over time when the first bias voltage BIAS1 and the second bias voltage BIAS2 are applied to the lower electrode 112 during the etching process cycle, according to one or more example embodiments. Due to the DC self-bias characteristics of the plasma described with reference to one or more example embodiments consistent with FIG. 3, the first bias voltage BIAS1 and the second bias voltage BIAS2, which have the same waveform and different DC levels, may form substantially the same substrate voltage Vwafer.

FIG. 11C illustrates IEDF over time when the first bias voltage BIAS1 and the second bias voltage BIAS2 are applied to the lower electrode 112 during the etching process cycle. When the first bias voltage BIAS1 is applied and when the second bias voltage BIAS2 is applied, the ion energy distribution may be substantially the same. In both cases, one may have a relatively low ion energy distribution of about 3000 eV and a relatively high ion energy distribution of about 6000 eV.

According to one or more example embodiments, the bias power supply device 1000 may control the direct current level of the bias voltage Vbias to minimize power consumption due to the bias voltage Vbias for forming the substrate voltage Vwafer. In detail, the bias power supply device 1000 may control a DC level of bias voltage Vbias so that the bias voltage Vbias becomes zero voltage during the period having the highest ratio among the first acceleration period, the second acceleration period, and the rest period.

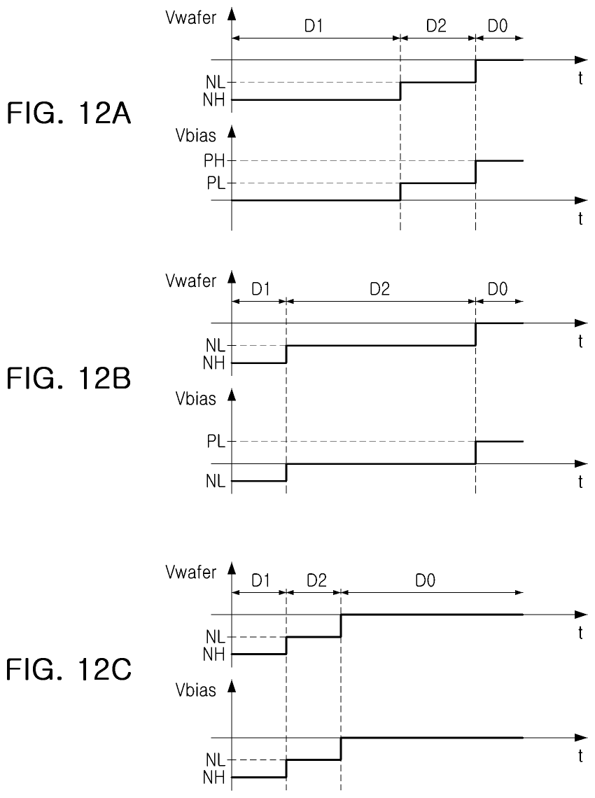

FIGS. 12A, 12B and 12C are diagrams illustrating bias voltage according to the duty ratio of the substrate voltage during one cycle of the etching process, according to one or more example embodiments.

FIGS. 12A, 12B and 12C illustrate the bias voltage Vbias according to the duty ratio of the first acceleration period, the second acceleration period, and the rest period during the etching process cycle, according to one or more example embodiments.

FIG. 12A illustrates the substrate voltage Vwafer and bias voltage Vbias when the ratio D1 of the first acceleration period is greater than the threshold. For example, the threshold may be 0.5.

If a voltage having the same DC level as the substrate voltage Vwafer is applied as the bias voltage Vbias, power of the bias power supply device 1000 may be consumed to apply a negative voltage during the first acceleration period and the second acceleration period. When the first acceleration period is the longest, if power is consumed during the first acceleration period, the power consumption of the etching process cycle may increase.

According to one or more example embodiments, the bias power supply device 1000 may control the direct current level of the bias voltage Vbias so that a zero voltage is applied during the first acceleration period. For example, the bias voltage Vbias may have a zero voltage during the first acceleration period, may have a positive voltage PL at the first level during the second acceleration period, and may have a positive voltage PH of a second level, greater than the first level, during the rest period. The bias power supply device 1000 may consume power during the second acceleration period and the rest period, and may not consume power during the longest first acceleration period, and thus, power consumption of the etching process cycle may be reduced.

FIG. 12B illustrates the substrate voltage Vwafer and bias voltage Vbias when the ratio D2 of the second acceleration period is greater than the threshold, according to one or more example embodiments. For example, the threshold may be 0.5.

According to one or more example embodiments, the bias power supply device 1000 may control the direct current level of the bias voltage Vbias so that a zero voltage is applied during the second acceleration period. For example, the bias voltage Vbias may have a third level negative voltage NL during the first acceleration period and a zero voltage during the second acceleration period, and may have a first level positive voltage PL during the rest period. Because the bias power supply device 1000 may not consume power during the longest second acceleration period, the power consumption of the etching process cycle may be reduced.

FIG. 12C illustrates the substrate voltage Vwafer and the bias voltage Vbias when the ratio D1 of the first acceleration period and the ratio D2 of the second acceleration period are the threshold or less. According to one or more example embodiments, a zero voltage may be applied to the bias power supply device 1000 during the rest period, and a negative voltage NH of a fourth level greater than the third level may be applied during the first acceleration period, and the DC level of the bias voltage Vbias may be controlled so that the third level of negative voltage NL is applied during the second acceleration period.

Meanwhile, referring to FIGS. 12A, 12B and 12C, the bias power supply device 1000 may form at least two levels of positive voltages PH and PL, a zero voltage, and at least two levels of negative voltages NH and NL, in the load. For example, the bias power supply device 1000, in addition to that described with reference to one or more example embodiments consistent with FIG. 7, may further include a switch that selectively turns ON and OFF an additional load that may reduce the voltage applied to the load L. The bias power supply device 1000 may form various levels of positive and negative voltages by turning the switch ON and OFF.

However, one or more example embodiments are not limited thereto, and the bias power supply device 1000 may have the same circuit structure as described with reference to FIG. 7, and various levels of positive and negative voltages may be formed by controlling the voltage level of the direct current power source Vdc as well as the states of the first switch pair S1, ˜S1 and the second switch pair S2, ˜S2, and positive and negative voltages of various levels may be formed by using a plurality of direct current power sources having different levels.

In one or more example embodiments, in the plasma etching device 100, unlike what is described with reference to one or more example embodiments consistent with FIGS. 12A, 12B and 12C, it may be controlled that a relatively low level of negative voltage is applied during the first acceleration period of the process cycle, a relatively high level of negative voltage is applied during the second acceleration period, and a positive voltage close to zero voltage is applied during the remaining time. According to one or more example embodiments, the bias power supply device 1000 may also control a DC level of bias voltage Vbias, such that the bias voltage Vbias becomes zero voltage during the period having the highest ratio among the first acceleration period, the second acceleration period, and the rest period.

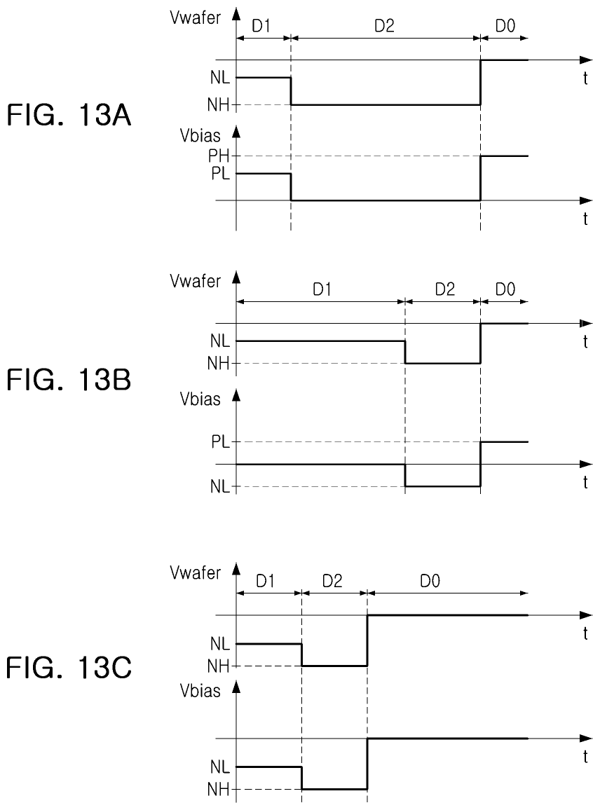

FIGS. 13A, 13B and 13C are diagrams illustrating bias voltage according to the duty ratio of the substrate voltage in one cycle of the etching process, according to one or more example embodiments.

FIGS. 13A, 13B and 13C illustrate the bias voltage Vbias according to the duty ratio of the first acceleration period, the second acceleration period, and the rest period during the etching process cycle.

FIG. 13A illustrates the substrate voltage Vwafer and bias voltage Vbias when the ratio D2 of the second acceleration period is greater than the threshold, according to one or more example embodiments. For example, the threshold could be 0.5.

According to one or more example embodiments, the bias power supply device 1000 may control the DC level of the bias voltage Vbias, such that the bias voltage Vbias has a zero voltage during the second acceleration period, a first level positive voltage PL during the first acceleration period, and a second level positive voltage PH higher than the first level during the rest period.

FIG. 13B illustrates the substrate voltage Vwafer and bias voltage Vbias when the ratio D1 of the first acceleration period is greater than the threshold, according to one or more example embodiments. For example, the threshold may be 0.5.

According to one or more example embodiments, the bias power supply device 1000 may control a DC level of bias voltage Vbias, such that the bias voltage Vbias has a zero voltage during the first acceleration period, a third level of negative voltage NL during the second acceleration period, and a first level of positive voltage PL during the rest period.

FIG. 13C illustrates the substrate voltage Vwafer and bias voltage Vbias when the ratio D1 of the first acceleration period and the ratio D2 of the second acceleration period are both less than the threshold, according to one or more example embodiments. For example, the threshold may be 0.5.

The bias power supply device 1000 may control a DC level of bias voltage Vbias, such that a zero voltage is applied during the rest period, a third level negative voltage NL is applied during the first acceleration period, and a fourth level negative voltage NH, greater than the third level, is applied during the second acceleration period.

According to one or more example embodiments described with reference to FIGS. 13A, 13B and 13C, the bias power supply device 1000 may control the direct current level of the bias voltage Vbias so that the bias voltage Vbias has a zero voltage during the longest period of the first etching period, the second etching period, and the rest period. Power consumption may be reduced by reducing the time power is consumed during the etching process cycle.

According to one or more example embodiments, the bias power supply device 1000 may control the direct current level of the non-sinusoidal power, so that during one process cycle, a zero voltage is applied to the lower electrode during the longest period among one or more acceleration periods for accelerating ions in the plasma and a rest period excluding the one or more acceleration periods, thereby increasing the maximum duty ratio during the acceleration period while suppressing power consumption, and extending the range of possible duty ratios.

Therefore, the bias power supply device 1000 according to one or more example embodiments may expand the scope of search to find the optimal duty ratio of the etch time to optimize the etch time, passivation time, and exhaust time of the plasma processing apparatus 100, and may increase UPEH while suppressing power consumption.

As set forth above, in a plasma processing apparatus according to one or more example embodiments, during one cycle of a plasma processing process, the duty ratio of an etching period may be set to 0.5 or more while the duty ratio of high-frequency bias power is controlled to be 0.5 or less, and thus, UPEH may be increased while suppressing an increase in power consumption.

Because a plasma processing apparatus according to one or more example embodiments may increase the range of a duty ratio of an etching period while power consumption is suppressed, the scope of the search for optimizing an etch period may be expanded.

While one or more example embodiments have been particularly illustrated and described above, it will be apparent to those skilled in the art that modifications and variations in form and details may be made therein without departing from the spirit and scope of the appended claims.

What is claimed is:

1. A plasma processing apparatus comprising:
a chamber body comprising a chamber;
an electrostatic chuck supporting a substrate within the chamber body and comprising a lower electrode;
a high-frequency power supply device configured to supply high-frequency power to generate plasma with gas supplied to the chamber; and
a bias power supply device configured to supply pulse power configured for ion acceleration to the lower electrode,
wherein the bias power supply device is configured to apply a positive voltage pulse having a duty ratio of (1-D) to the lower electrode, where D is a real number between 0 and 1, when a target duty ratio D of an acceleration period for accelerating ions in the plasma during a process cycle is greater than a threshold.

2. The plasma processing apparatus of claim 1, wherein the bias power supply device is configured to apply a negative voltage pulse having the target duty ratio D to the lower electrode when the target duty ratio D is less than or equal to the threshold.

3. The plasma processing apparatus of claim 1, wherein the bias power supply device is configured to control the positive voltage pulse to have a zero voltage during the acceleration period during the process cycle and to have a positive voltage during a rest period excluding the acceleration period, and
wherein the bias power supply device is configured to control the positive voltage pulse such that a lower surface of the substrate has a negative voltage during the acceleration period and the lower surface of the substrate has a plasma voltage during the rest period, due to the positive voltage pulse and DC self-bias characteristics of the plasma.

4. The plasma processing apparatus of claim 3, wherein a magnitude of the positive voltage that the positive voltage pulse exhibits during the rest period is greater than or equal to a magnitude of the negative voltage that the lower surface of the substrate exhibits during the acceleration period.

5. The plasma processing apparatus of claim 1, wherein the threshold is 0.5.

6. The plasma processing apparatus of claim 1, wherein the bias power supply device includes:
a load provided between a first node connected to the lower electrode and a second node connected to ground;
a first switch pair comprising:
a first switch connected between the first node and a third node; and
a first complementary switch connected between the first node and a fourth node and configured to operate complementary to the first switch:
a second switch pair comprising:
a second switch connected between the second node and the third node; and
a second complementary switch connected between the second node and the fourth node and configured to operate complementary to the second switch; and
a direct current power source connected between the third node and the fourth node.

7. The plasma processing apparatus of claim 6, wherein the bias power supply device is configured to apply the positive voltage pulse having the duty ratio of (1-D) to the lower electrode by maintaining the first switch in an ON state and controlling an ON state of the second switch to have the target duty ratio D.

8. The plasma processing apparatus of claim 6, wherein the bias power supply device is configured to apply a negative voltage pulse having the target duty ratio D to the lower electrode by maintaining the first switch in an OFF state and controlling an ON state of the second switch to have a duty ratio of (1-D), when the target duty ratio D is the threshold or less.

9. The plasma processing apparatus of claim 1, wherein the plasma processing apparatus is configured to perform an etching operation of the substrate during the acceleration period, and is configured to perform a passivation operation and an exhaust operation during a rest period excluding the acceleration period during the process cycle.

10. The plasma processing apparatus of claim 1, wherein the plasma processing apparatus further includes:
an upper electrode on an upper portion or a side portion of the chamber body; and
an induction electrode disposed between the upper electrode and the lower electrode, and provided inside the chamber.

11. A plasma processing apparatus comprising:
a chamber body comprising a chamber;
an electrostatic chuck supporting a substrate within the chamber body and comprising a lower electrode;
a high-frequency power supply device configured to supply high-frequency power to generate plasma with gas supplied to the chamber; and
a bias power supply device configured to supply non-sinusoidal power to the lower electrode for ion acceleration,
wherein the bias power supply device is configured to control a direct current level of the non-sinusoidal power using a ratio of a first acceleration period during a process cycle, in which ions in the plasma are accelerated to have a first energy, a ratio of a second acceleration period during which ions in the plasma are accelerated to have a second energy, and a ratio of a rest period excluding the first acceleration period and the second acceleration period.

12. The plasma processing apparatus of claim 11, wherein the first energy is higher than the second energy, and
wherein the bias power supply device is configured to control the direct current level of the non-sinusoidal power, such that when the ratio of the first acceleration period is greater than a threshold, the non-sinusoidal power exhibits a zero voltage during the first acceleration period, exhibits a positive voltage of a first level during the second acceleration period, and exhibits a positive voltage of a second level greater than the first level during the rest period.

13. The plasma processing apparatus of claim 12, wherein the threshold is 0.5.

14. The plasma processing apparatus of claim 11, wherein the first energy is higher than the second energy, and
wherein the bias power supply device is configured to control the direct current level of the non-sinusoidal power, such that when the ratio of the second acceleration period is greater than a threshold, the non-sinusoidal power exhibits a negative voltage during the first acceleration period, exhibits a zero voltage during the second acceleration period, and exhibits a positive voltage during the rest period.

15. The plasma processing apparatus of claim 11, wherein the first energy is higher than the second energy, and
wherein the bias power supply device is configured to control the direct current level of the non-sinusoidal power, such that when the ratios of the first acceleration period and the ratio of the second acceleration period are less than or equal to a threshold, the non-sinusoidal power exhibits a negative voltage of a third level during the first acceleration period, exhibits a negative voltage of a fourth level smaller than the third level during the second acceleration period, and exhibits a zero voltage during the rest period.

16. The plasma processing apparatus of claim 11, wherein the first energy is lower than the second energy, and
wherein the bias power supply device is configured to control the direct current level of the non-sinusoidal power, such that when the ratio of the second acceleration period is greater than a threshold, the non-sinusoidal power exhibits a positive voltage of a first level during the first acceleration period, exhibits a zero voltage during the second acceleration period, and exhibits a positive voltage of a second level greater than the first level during the rest period.

17. The plasma processing apparatus of claim 11, wherein the first energy is lower than the second energy, and
wherein the bias power supply device is configured to control the direct current level of the non-sinusoidal power, such that when the ratio of the first acceleration period is greater than a threshold, the non-sinusoidal power exhibits a zero voltage during the first acceleration period, exhibits a negative voltage during the second acceleration period, and exhibits a positive voltage during the rest period.

18. The plasma processing apparatus of claim 11, wherein the first energy is lower than the second energy, and
wherein the bias power supply device is configured to control the direct current level of the non-sinusoidal power, such that when the ratio of the first acceleration period and the ratio of the second acceleration period are less than or equal to a threshold, the non-sinusoidal power exhibits a negative voltage of a fourth level during the first acceleration period, exhibits a negative voltage of a third level greater than the fourth level during the second acceleration period, and exhibits a zero voltage during the rest period.

19. The plasma processing apparatus of claim 11, wherein the bias power supply device is configured to control the direct current level of the non-sinusoidal power, such that the non-sinusoidal power exhibits a zero voltage during a period with a highest ratio among the first acceleration period, the second acceleration period, and the rest period.

20. A plasma processing apparatus comprising:
a chamber body comprising a chamber;
an electrostatic chuck supporting a substrate within the chamber body and comprising a lower electrode;
a high-frequency power supply device configured to supply high-frequency power to generate plasma with gas supplied to the chamber; and
a bias power supply device configured to supply non-sinusoidal power to the lower electrode for ion acceleration,
wherein the bias power supply device is configured to control a direct current level of the non-sinusoidal power, such that a zero voltage is applied to the lower electrode during a longest period among one or more acceleration periods for accelerating ions in the plasma and a rest period excluding the one or more acceleration periods during one process cycle.
